(19) United States
(12) Patent Application Publication
(10) Pub. No.: US 2007/0139098 A1
(43) Pub. Date: Jun. 21, 2007

(54) Wearout compensation mechanism using back bias technique

(75) Inventors: Edgardo F. Klass, Palo Alto, CA (US); Sribalan Santhanam, Palo Alto, CA (US)

Correspondence Address: MEYERTONS, HOOD, KIVLIN, KOWERT & GOETZEL, P.C., P.O. BOX 398, AUSTIN, TX, 78767-0398, US

(73) Assignee: P.A. Semi, Inc., Santa Clara, CA (US)

(21) Appl. No.: 11/304,830

(22) Filed: Dec. 15, 2005

(51) Int. Cl. H03K 3/01

(52) U.S. Cl. 327/534

(57) ABSTRACT

In one embodiment, an integrated circuit comprises a first circuit and a control unit coupled to the first circuit. The first circuit comprises at least one transistor and implements one or more operations for which the integrated circuit is designed. The control unit is configured to generate at least one substrate bias voltage for the first circuit.

### BACKGROUND

1. Field of the Invention

This invention is related to the field of integrated circuits and, more particularly, to the application of back bias (or substrate bias) voltages to transistors in an integrated circuit.

2. Description of the Related Art

Integrated circuits are a key component of many electronic systems in use today, as well as many other products that do not appear to be electronic systems. Generally, an integrated circuit includes a semiconductor substrate such as silicon or other semiconductor elements or compounds. Various other substances (e.g. elements) are forced into the substrate to form transistors and other circuit structures, and metallization layers are added to interconnect the substrate structures. The metallization layers may comprise any sort of conductive material (e.g. aluminum, copper, titanium, combinations thereof, etc.) and insulation material included between the conductors formed from the conductive material (both horizontally and vertically).

In metal-oxide-semiconductor (MOS) transistors, a gate node that controls the conductivity of the transistor is separated from the semiconductor surface by an insulating oxide layer. The oxide layer is over an area of the substrate that is one conductivity type (e.g. P-type or N-type for CMOS), and adjacent source/drain areas are of the opposite conductivity type. By applying an appropriate voltage on the gate node (as compared to the voltage on a source or drain region), a channel of conductivity is created in the area underneath the oxide layer and current can be conducted from the source to the drain.

Below a certain absolute voltage difference between the gate and source (negative for one conductivity type and positive for the other), the channel has not yet been fully formed and substantially no current flow occurs in the transistor (although small amounts of current such as leakage current do occur during these times). The transistor is often referred to as “off” in this condition. Above the voltage difference, the channel becomes conductive and substantial current flow begins. Within a relatively small additional increase in the voltage different, the transistor is referred to as being “saturated” or (“on”). Continuing to increase the voltage difference above saturation leads to additional current, but at a relatively small rate of increase compared to the increase as saturation is reached. The voltage difference at which saturation is reached or nearly reached is typically referred to as the “threshold voltage” of the transistor.

Circuitry included in the integrated circuit is designed (from a timing standpoint) under the assumption that the threshold voltage will be approximately a fixed, predetermined voltage. The fixed voltage may vary within a window based on semiconductor fabrication process parameters, temperature, etc. However, over long term usage, the threshold voltage may shift (or experience “threshold voltage drift”) due to damage experienced by the integrated circuit. Generally, the threshold voltage shifts to a larger absolute magnitude, slowing down the operation of the integrated circuit as a whole since a larger voltage change on a gate node is required to switch a transistor on or off. Over time, the threshold voltage shift may cause the timing to change enough that the integrated circuit ceases to function. Thus, the integrated circuit reaches end of life, perhaps sooner than desired, due to the threshold voltage shift. Accordingly, threshold voltage shift presents a long term reliability problem for integrated circuits.

A common source of threshold voltage shift is “hot carrier effects” that may be experienced by transistors. Hot carrier effects are generally any effects that occur due to the injection of carriers (electrons or holes) into the insulating layer between the control node of the transistor and the semiconductor substrate (e.g. into the oxide layer between the gate and the substrate in an MOS transistor). Injection of the carriers into the insulating layer essentially creates a voltage in the insulating layer that must be overcome before the threshold voltage difference between the control node and the source begins to be developed.

In complementary MOS (CMOS) circuits that include both P-channel MOS (PMOS) and N-channel MOS (NMOS) transistors, both PMOS and NMOS transistors can suffer from hot carrier effects. Typically, hot carrier injection into NMOS transistors causes about 1% of long term wearout of integrated circuits, but can be up to 10%. Injection into PMOS transistors, particularly from Negative Bias Temperature Instability (NBTI), causes about 10% of the long term wearout of integrated circuits. One reason for this is that hot carrier injection in NMOS transistors occurs when transistors are in saturation, while NBTI occurs at static bias conditions.

### SUMMARY

In one embodiment, an integrated circuit comprises a first circuit and a control unit coupled to the first circuit. The first circuit comprises at least one transistor and implements one or more operations for which the integrated circuit is designed. The control unit is configured to generate at least one substrate bias voltage for the first circuit, wherein the control unit comprises a second circuit that approximates a delay of at least one critical path in the first circuit. The control unit is configured to generate the substrate bias voltage responsive to operation of the second circuit.

In another embodiment, an integrated circuit comprises the first circuit and a control unit coupled thereto. The control unit is configured to generate at least one substrate bias voltage for the first circuit to compensate for hot carrier effects on a threshold voltage of the transistor. The first circuit is configured to generate at least one feedback control signal to the control unit, and the control unit is configured to generate the at least one substrate bias voltage responsive to the feedback control signal.

In one embodiment, a method comprises monitoring one or more transistors to detect a change in a threshold voltage of the transistors over time due to hot carrier effects on the transistors; and modifying at least one substrate bias voltage supplied to transistors in circuitry that implements one or more operations for which an integrated circuit is designed responsive to the monitoring, the modifying performed to compensate for the change in a threshold voltage of the transistors.

### BRIEF DESCRIPTION OF THE DRAWINGS

The following detailed description makes reference to the accompanying drawings, which are now briefly described.

FIG. 1 is a block diagram of one embodiment of an integrated circuit.

FIG. 2 is a block diagram of another embodiment of an integrated circuit.

FIG. 3 is a timing diagram illustrating examples of voltages over time.

FIG. 4 is a block diagram of one embodiment of transistors on an integrated circuit and certain connections thereto.

FIG. 5 is a flowchart illustrating one embodiment of using substrate bias voltages to compensate for threshold voltage drift.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF EMBODIMENTS

In some embodiments, an integrated circuit includes a control unit that generates one or more substrate bias voltages for the transistors used in the core circuit of the integrated circuit. The core circuit may be the circuitry that performs one or more operations for which the integrated circuit is designed. For example, if the integrated circuit includes a processor, the core circuit may include the circuitry that executes instructions defined in the instruction set architecture implemented by the processor. If the integrated circuit includes a bus bridge, the core circuit may include the circuitry that interfaces to each bus and queues for managing cross communication on the buses. If the integrated circuit includes a memory controller, the core circuit may include the circuitry that interfaces to the memory modules, queue for memory accesses, etc. Integrated circuits may be designed to perform different operations in different embodiments.

The control unit may generate the substrate bias voltage(s) for the core circuit to compensate for threshold voltage shift (e.g. caused by hot carrier injection effects). When no compensation is provided, the substrate bias voltages are nominally set at one of the supplies (e.g. the power supply voltage, often denoted V_{DD}, or the ground voltage, often denoted V_{SS}). A nominal voltage is the voltage assumed for design purposes. The actual voltage during may vary somewhat from the nominal voltage (e.g. due to transient power effects, noise, imperfect power supplies, etc.). In CMOS circuitry, for example, the PMOS transistors usually have the substrate bias voltage (also often referred to as the back bias) nominally set at V_{DD} and the NMOS transistors usually have the substrate bias voltage nominally set at V_{SS}. Transistors are often shown in schematics with a B (or bulk) input to illustrate the substrate bias voltage.

If the substrate bias voltages are modified from their nominal settings (decreased for the PMOS substrate bias voltage, increased for the NMOS substrate bias voltage), the threshold voltage for the transistor decreases. Accordingly, wearout of the integrated circuit due to hot carrier effects on the transistors may be forestalled by adjusting the substrate bias voltages. The control unit may be designed to reduce the PMOS substrate bias voltage and/or increase the NMOS substrate bias voltage to compensate for threshold voltage drift due to hot carrier injection.

In some embodiments, only one substrate bias voltage may be modified by the control unit. For example, in some CMOS circuits, failures due to PMOS threshold voltage drift may be significantly more prevalent then failures due to NMOS threshold voltage drift. Accordingly, only the PMOS substrate bias voltage may be adjusted in some embodiments. Other embodiments may modify both substrate bias voltages.

As used herein, a substrate bias voltage may be a voltage that is applied to the semiconductor substrate material into which a transistor is fabricated. In some cases, the substrate bias voltage is also referred to as the back bias voltage. In some cases, the semiconductor substrate material may be a well of substrate material that is doped to the opposite conductivity type as the source/drain regions of the transistor. For example, in some cases, an N-type well (N-well) is created to permit PMOS transistors to be fabricated (having P-type source/drain regions) and the substrate prior to forming wells may be P-type. NMOS transistors may be fabricated directly into a P-type semiconductor substrate (with no well). Alternatively, dual-well technologies may be used in which both NMOS and PMOS transistors are fabricated in wells of opposite conductivity. In still other embodiments, the semiconductor substrate may be N-type and P-type wells (P-wells) may be created into which the NMOS transistors may be fabricated while PMOS transistors may be fabricated directly into the N-type semiconductor substrate. Generally, a well may be an area of semiconductor material that is doped with the opposite conductivity of the source/drain regions of the transistors that are to be fabricated in the well. The well may also be the opposite conductivity of the semiconductor substrate, in some cases, or the substrate may be undoped (neutral conductivity). In other embodiments, transistors may be fabricated in other ways (e.g. silicon on insulator (SOI)). In the embodiments below, CMOS transistors are used as the examples. Other embodiments may implement any other transistor, as desired. Furthermore, N-well technology will be used as the example but other examples could be P-well or dual well.

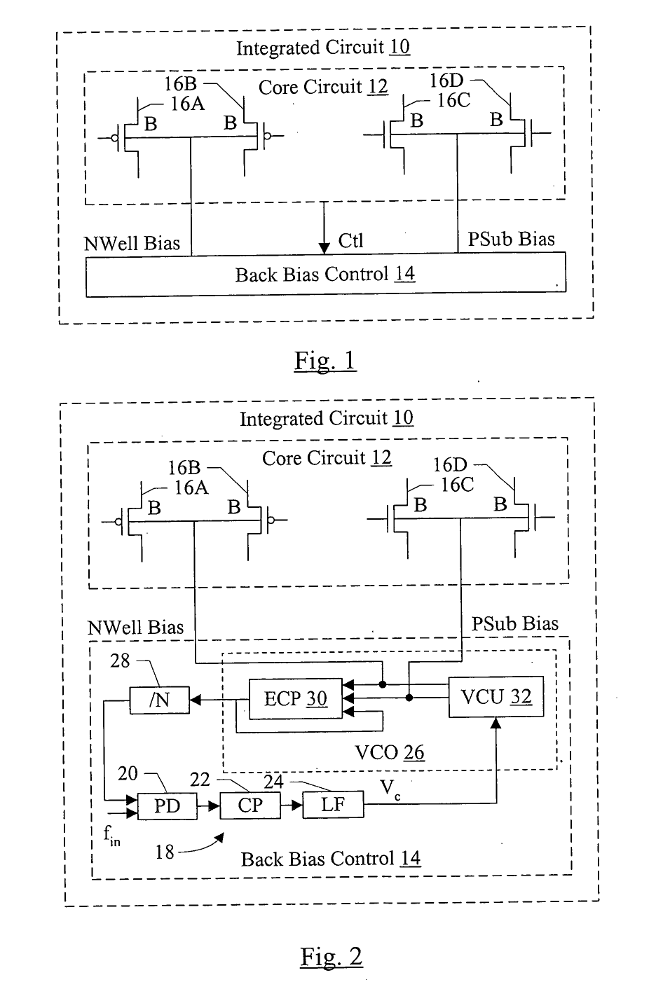

Turning now to FIG. 1, a block diagram of one embodiment of an integrated circuit 10 is shown. In the embodiment of FIG. 1, the integrated circuit 10 includes a core circuit 12 and a back bias control unit 14. The back bias control unit 14 is coupled to receive one or more feedback signals from the core circuit 12 (Ctl in FIG. 1), and is configured to generate one or more substrate voltages to the core circuit 12 (e.g. the NWell Bias and the P substrate (PSub) Bias illustrated in FIG. 1). In the illustrated embodiment, the core circuit 12 includes one or more transistors such as PMOS transistors 16A-16B and NMOS transistors 16C-16D that are part of the circuitry implementing the operation(s) for which the integrated circuit 10 is designed. Only 4 transistors are shown for simplicity in the drawing, but any number of transistors of either conductivity type may be included in various embodiments. The PMOS transistors 16A-1 6B have a bulk (B) input connected to the NWell Bias output from the back bias control unit 14 and the NMOS transistors 16C-16D are coupled to receive the PSub Bias output from the back bias control unit 14. Source, drain, and gate connections are not illustrated in FIG. 1.

In the embodiment of FIG. 1, the core circuit 12 may monitor operation of its transistors and provide feedback directly to the back bias control unit 14 to cause modifications in the substrate bias voltages generated by the back bias control unit 14. If the feedback indicates no compensation is needed, the back bias control unit 14 may generate the nominal substrate bias voltages (e.g. approximately V_{DD} and V_{SS} for the NWell Bias and PSub Bias, respectively). If the feedback indicates that compensation is needed, then the back bias control unit 14 may decrease the NWell Bias and/or increase the PSub Bias in response. The feedback signals may include separate feedback signals for PMOS and NMOS transistors, or a single set of one or more feedback signals applied for both transistor types. The feedback signals may request a particular substrate bias voltage, or may be a relative request (e.g. increase or decrease the current substrate bias voltage).

The core circuit 12 may implement any self-monitoring mechanism to generate the feedback. For example, the core circuit 12 may compare an expected output from internal circuitry to the actual output, to detect that the expected output is not being generated quickly enough. The core circuit 12 may generate a signature for a known input or set of inputs, and may compare the signature to an expected signature. Alternatively, circuitry to measure the hot carrier injection at representative transistors may be used.

In other embodiments, the back bias control unit 14 may monitor to detect when substrate bias voltages are to be modified. For example, the embodiment of FIG. 2 may be used. In FIG. 2, the integrated circuit 10 includes the core circuit 12 including the transistors 16A-16D having bulk (B) connections to the NWell Bias and PSub Bias as illustrated in FIG. 2. The core circuit 12 in FIG. 2 may not include the self-monitoring features mentioned above, in some embodiments. The back bias control unit 14 may include a circuit (equivalent critical path (ECP) circuit 30) that the back bias control unit 14 may use to monitor the operation of the core circuit 12 and to determine when to modify the substrate bias voltages to the core circuit 12.

The core circuit 12 may include one or more “critical paths”. Generally, a path may comprise one or more circuits and interconnect (or “wire”) between an input signal and an output signal. Each path may have an associated delay (which may vary based on process characteristics of a given integrated circuit and/or operating temperature of the given integrated circuit). A critical path may have an associated delay that is greater than other paths in the core circuit 12 (or greater than most other paths). Critical paths may be key to determining if the core circuit 12 will operate correctly at a given operating frequency. If the critical paths evaluate properly prior to the end of the clock cycle at the given operating frequency, other paths should also evaluate properly.

The equivalent critical path circuit 30 may approximate one or more critical paths in the core circuit 12. By monitoring the operation of the ECP circuit 30, the back bias control unit 14 may determine if the operation is slowing (e.g. due to threshold voltage drift) and thus may modify the substrate bias voltage(s) to compensate for the threshold voltage drift to speed the operation of the circuit. Since the ECP circuit 30 approximates the critical path(s) in the core circuit 12, the ECP circuit 30 should be affected by hot carrier injection in a similar fashion to the core circuit 12, and thus performance should degrade in the ECP 30 in a similar fashion to the degradation of the core circuit 12.

The ECP circuit 30 may be constructed in a variety of fashions. For example, as the design of the integrated circuit 10 is finalized, one or more critical paths in the design may be identified via timing analysis tools. The critical paths may be extracted from the design, and the ECP circuit 30 may be constructed with the same circuitry as the actual critical paths (and with the same amount of interconnect delay, or wire delay, between the circuitry). In other embodiments, the percentage of delay attributable to circuit delay (e.g. gate delay) and the percentage attributable to wire delay may be calculated for one or more critical paths. The ECP circuit 30 may include circuitry to provide the circuit delay percentage and may include interconnect to provide the wire delay percentage. In yet another embodiment, the ECP circuit 30 may include N circuits (where N is an integer greater than 1). Each circuit is coupled to receive the same input and to provide the output. Each of the N circuits may be designed to model the critical path delay with a different percentage of the delay attributable to circuit delay and to wire delay. For example, if four circuits were included, one circuit may model the critical path delay as 100% circuit delay, 0% wire delay; a second circuit may model the critical path delay as 75% circuit delay, 25% wire delay; a third circuit may model the critical path delay as 50% circuit delay, 50% wire delay; and a fourth circuit may model the critical path delay as 25% circuit delay, 75% wire delay. Once the design of the integrated circuit 12 is finalized, the critical path or paths in the integrated circuit 12 may be characterized as to how much delay is attributable to circuit delay and wire delay. The circuit that most closely models the critical path delay(s) may be activated using fuses (or may be selected in a programmable fashion).

The back bias control circuit 14 may monitor the ECP circuit 30 in any desired fashion. For example, in the illustrated embodiment, the output of the ECP circuit 30 may be coupled to its input. Accordingly, the ECP circuit 30 may oscillate. (In this embodiment, either the ECP circuit 30 may include an odd number of inversions or an inverter may be placed in the feedback path from the output to the input). The back bias control circuit 14 may measure the frequency of oscillation to detect a slow down in the circuit operation over time. In other embodiments, the output of the ECP circuit 30 may not be coupled to its input. Instead, the back bias control unit 14 may launch an input into the ECP circuit 30 and sample the output at various times relative to the launch time. If the corresponding output transition is sampled later in time than previous iterations, the back bias control circuit 14 may detect that the ECP circuit's response is slowing. In such embodiments, the back bias control unit 14 may use the measurements to determine the magnitude of the substrate bias voltages. Alternatively, the back bias control unit 14 may modify the substrate bias voltages to the ECP circuit 30 until the desired response speed is achieved. The back bias control unit 14 may then modify the substrate bias voltages supplied to the core circuit 12.

In the illustrated embodiment, the ECP circuit 30 is included in a voltage-controlled oscillator (VCO 26). The control voltage input to the VCO (V_{c}) may be varied to control the oscillation of the ECP circuit 30. More particularly, the substrate bias voltages of the ECP circuit 30 may be derived from the control voltage input. In the illustrated embodiment, the VCO 26 includes a voltage control unit (VCU) 32 coupled to receive the control voltage input and configured to generate the substrate bias voltages for the ECP circuit 30. The same substrate bias voltages may also be provided to the core circuit 12, as shown in FIG. 2. Alternatively, the substrate bias voltages to the core circuit 12 may be generated separately.

The VCU 32 may drive the substrate bias voltages in any desired fashion. One of the substrate bias voltages may be a pass through of the control voltage (e.g. the PSub Bias voltage). The other substrate bias voltage may be the control voltage subtracted from the power supply voltage (e.g. the NWell Bias voltage). Other embodiments may derive both substrate bias voltages from the control voltage.

In the embodiment of FIG. 2, the VCO 26 is part of a phase-locked loop (PLL) 18. Specifically, in the illustrated embodiment, the PLL 18 includes a phase detector (PD) 20, a charge pump (CP) 22, a loop filter (LF) 24, the VCO 26, and a frequency divider 28. The phase detector 20 is coupled to receive a reference frequency (fᵢₙ) and the output of the frequency divider 28. The frequencies at which the PLL 18 locks are multiples of the reference frequency, wherein the current multiple is equal to the divisor in the frequency divider 28.

When a given frequency is programmed into the PLL 18 via the frequency divider 28, the PLL 18 locks to the given frequency. Once lock is achieved in the PLL 18, the ring oscillator formed from the ECP circuit 30 is oscillating at the N*fᵢₙ frequency (where N is the divisor programmed into the frequency divider 28). Since the ECP circuit 30 models the delay of the critical path, the control voltage to the VCO is the supply voltage at which the critical path evaluates in time to meet the desired operating frequency (that is, the critical path evaluates within the clock cycle at the desired operating frequency, and thus the integrated circuit 10 may be expected to operate as designed).

It is noted that, to produce one period of oscillation from the ring oscillator formed by the ECP circuit 30, the ECP circuit 30 evaluates twice (once to produce a rising edge of the oscillation, and once to produce the falling edge of the oscillation in response to the rising edge feeding back to the input). Accordingly, to measure the voltage at which the critical path evaluates within one period of a desired operating frequency, the frequency divider 28 may be programmed so that the PLL locks at a frequency that is ½ of the desired operating frequency.

The operation of the PLL 18 may be as follows: The phase detector 20 detects phase differences between the output of the frequency divider 28 and the reference frequency. If a phase difference is detected, the phase detector 20 controls the charge pump 22 to either increase or decrease the control voltage on the control voltage input to the VCO 26. If the reference frequency is ahead, the phase detector 20 may increase the control voltage and if the reference frequency is behind, the phase detector 20 may decrease the control voltage. The control voltage may be filtered by the loop filter 24, and supplied to the VCO 26. The output of the VCO 26 (the output of the ring oscillator formed by the ECP circuit 30) is supplied as the input the frequency divider 28. Thus, when the PLL 18 locks, the VCO 26 is oscillating at N times the reference frequency (and in phase with the reference frequency).

FIG. 2 does not explicitly illustrate the substrate bias voltages supplied to the PLL 18 blocks. In an embodiment implemented in an N-Well process, the PMOS transistors may be isolated from the NWell Bias by coupling the N-Wells of the PMOS transistors in the PLL 18 to V_{DD} (or some voltage other than the NWell Bias), but the NMOS transistors (fabricated directly into the P-type substrate) may not be isolated and thus the substrate bias voltage to the NMOS transistors in the PLL 18 may be controlled by PSub Bias. The opposite would be the case in P-Well process. In a dual well (or triple well) process, both types of transistors may be isolated from the adjustable substrate bias voltages. In such cases, each well in the PLL 18 transistors may be coupled to an appropriate fixed substrate bias voltage (e.g. V_{DD} or ground). In other cases, the PLL 18 design may incorporate the effects of the expected changes in the substrate bias voltages on the transistors in the PLL 18, to accurately set the substrate bias voltages.

In other embodiments, the back bias control unit 14 may implement two ECP circuits 30, one of which may be used to generate the NWell Bias voltage and the other of which may be used to generate the PSub Bias voltage. The two ECP circuits 20 may be included in two VCOs 26, which may be included in two PLLs 18. It is noted that, in some embodiments, the loop bandwidth of the PLL 18 may be relatively low (and/or in other embodiments the response time from detecting a difference in the operation of the ECP circuit 30 to changing one or both substrate bias voltages may be relatively high). The effects of hot carrier injection into the oxide layer are long term (e.g. measured in years, such as approximately 10 years to generation of a failure). Thus, the response need not be fast to appropriately adjust the substrate bias voltages.

In still other embodiments, the back bias control unit 14 may implement a combination of feedback from the core circuit 12 and the ECP circuit 30. The ECP circuit 30 may be monitored to detect hot carrier effects on the threshold voltage of the transistors in the core circuit 12, and the back bias control unit 14 may generate corresponding substrate bias voltages responsive to the monitoring. The feedback from the core circuit 12 may be used as a backup, to permit modification of the substrate bias voltages if the ECP circuit 30 does not accurately approximate the operation of the core circuit 12 over time.

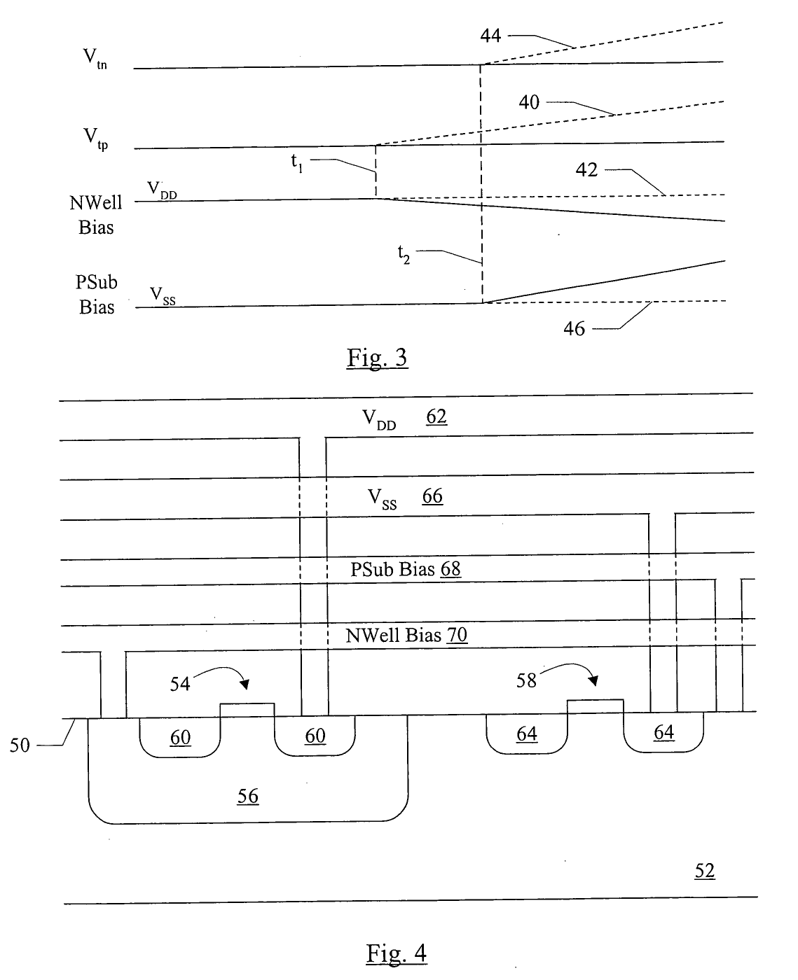

FIG. 3 is a simplified timing diagram illustrating the threshold voltages of the transistors in the integrated circuit 10 (Vₜₚ for PMOS transistors, Vₜₙ for NMOS transistors, both shown as positive values in FIG. 3) and the NWell Bias and PSub bias voltages. Time increases in the arbitrary units from left to right in FIG. 3, but generally the time illustrated in FIG. 3 is measured in years as an order of magnitude.

Initially, the threshold voltages of the transistors are at nominal levels and the substrate bias voltages are set at nominal levels. At a time t₁ (illustrated by a vertical dotted line labeled t₁ in FIG. 3) the effects of hot carrier injection on the PMOS transistors would cause the threshold voltage Vₜₚ to increase over time (dotted line 40). However, the back bias control unit 14 begins decreasing the NWell Bias voltage, thus permitting the Vₜₚ voltage to remain approximately constant. The dotted line 42 illustrates a flat NWell Bias voltage.

Similarly, at a time t₂ (illustrated by a vertical dotted line labeled t₂ in FIG. 3) the effects of hot carrier injection on the NMOS transistors would cause the threshold voltage Vₜₙ to increase over time (dotted line 44). However, the back bias control unit 14 begins increasing the PSub Bias voltage, thus permitting the Vₜₙ voltage to remain approximately constant. The dotted line 46 illustrates a flat PSub Bias voltage.

While linear wave forms are illustrated in FIG. 3 for simplicity, the wave forms may general vary in non-linear fashion over time. Furthermore, hot carrier injection may cause an increase in threshold voltage continuously over time, at a slow rate, but the rate has been exaggerated in FIG. 3 for illustrative purposes.

FIG. 4 is a block diagram of one embodiment of transistors fabricated on an integrated circuit 10 and connections thereto for one embodiment. A surface 50 of the semiconductor substrate 52 is shown. Above the surface 50 are various metallization layers of the integrated circuit 10. In this embodiment, the semiconductor substrate 52 is P-type conductivity, and thus a PMOS transistor 54 is fabricated in an N-well 56 that itself is fabricated in the semiconductor substrate 52. In contrast, an NMOS transistor 58 is fabricated directly into the semiconductor substrate 52 (i.e. with no well). The PMOS transistor 54 includes source/drain regions 60 fabricated in the N-well 56. One of the source/drain regions 60 is coupled to a power Supply (V_{DD}) plane 62. The NMOS transistor 54 similarly includes source/drain regions 64 fabricated in the semiconductor substrate 52, and one of the source/drain regions 64 may be coupled to a ground (V_{SS}) plane 66. Additionally, a PSub Bias plane 68 is coupled to the semiconductor substrate 52 and an NWell Bias plane 70 is coupled to the N-well 56.

The planes 62, 66, 68, and 70 and the vias to the surface 50 may be formed out of any conductive materials (e.g. aluminum, copper, tungsten, combinations thereof, etc.). The planes 62 and 66 may be powered during use, to the V_{DD} and V_{SS} voltages, respectively, via pins on the packaging to the integrated circuit 10. The planes 68 and 70 may be driven by the back bias control unit 14.

The taps from the planes 68 and 70 to the N-well(s) 56 and the semiconductor substrate 52 may be placed according to the resistivity of the substrate. Highly resistive substrates may lead to fine grained-placement of taps, whereas less resistive substrates may lead to coarse-grained placement of taps.

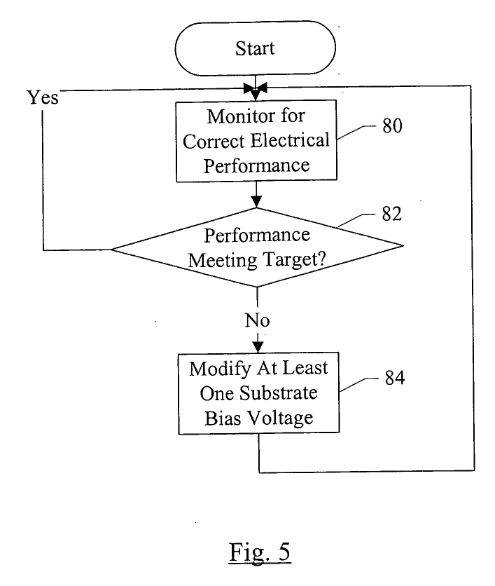

Turning now to FIG. 5, a flowchart illustrating one embodiment of a method is shown. While blocks are shown in a particular order for ease of understanding, other orders may be used. Blocks, combinations of blocks, and/or the flowchart as a whole may be pipelined over multiple clock cycles, in some embodiments.

The method includes monitoring for correct electrical performance of the core circuit 12 (block 80). The monitoring may be performed by the core circuit 12, the back bias control unit 14, or both, in various embodiments. The monitoring may include monitoring feedback from the core circuit 12, monitoring the ECP circuit, or both in various embodiments.

If the performance is meeting the target (e.g. the core circuit 12 operates correctly at the desired operating frequency—decision block 82, “yes” leg), the monitoring may continue. If the performance is not meeting the target (decision block “no” leg), then at least one of the substrate bias voltages may be modified (block 84) and the monitoring may continue.

Numerous variations and modifications will become apparent to those skilled in the art once the above disclosure is fully appreciated. It is intended that the following claims be interpreted to embrace all such variations and modifications.

What is claimed is:

1. An integrated circuit comprising:
a first circuit comprising at least one transistor, wherein the circuit implements one or more operations for which the integrated circuit is designed; and
a control unit coupled to the first circuit, wherein the control unit is configured to generate at least one substrate bias voltage for the first circuit, and wherein the control unit comprises a second circuit that approximates a delay of at least one critical path in the first circuit, and wherein the control unit is configured to generate the substrate bias voltage responsive to operation of the second circuit.

2. The integrated circuit as recited in claim 1 wherein the control unit comprises a voltage-controlled oscillator (VCO), and wherein the second circuit is included in the VCO and oscillates.

3. The integrated circuit as recited in claim 1 wherein a control voltage input of the VCO is used to derive at least one second substrate bias voltage supplied to the second circuit.

4. The integrated circuit as recited in claim 3 wherein the VCO includes a voltage control unit coupled to receive the control voltage and generate the at least one second substrate bias voltage responsive to the control voltage.

5. The integrated circuit as recited in claim 2 wherein the control unit comprises at least one phase-locked loop (PLL), and wherein the VCO is included in the PLL, and wherein the PLL, when locked, ensures that the second circuit evaluates at a given clock frequency and the at least one second substrate bias voltage supplied to the second circuit is the at least one substrate bias voltage supplied to the first circuit by the control unit.

6. The integrated circuit as recited in claim 1 wherein the at least one substrate bias voltage is applied to a well into which the transistor is fabricated in the integrated circuit.

7. The integrated circuit as recited in claim 6 wherein the at least one substrate bias voltage further includes a third substrate bias voltage that is applied to a substrate into which the well is fabricated.

8. The integrated circuit as recited in claim 7 wherein the first circuit includes a second transistor that is fabricated in the substrate without the well.

9. An integrated circuit comprising:
a first circuit comprising at least one transistor, wherein the circuit implements one or more operations for which the integrated circuit is designed; and
a control unit coupled to the first circuit, wherein the control unit is configured to generate at least one substrate bias voltage for the first circuit to compensate for hot carrier effects on a threshold voltage of the transistor;
wherein the first circuit is configured to generate at least one feedback control signal to the control unit, and wherein the control unit is configured to generate the at least one substrate bias voltage responsive to the feedback control signal.

10. The integrated circuit as recited in claim 9 wherein the at least one substrate bias voltage is applied to a well into which the transistor is fabricated in the integrated circuit.

11. The integrated circuit as recited in claim 10 wherein the at least one substrate bias voltage further includes a third substrate bias voltage that is applied to a substrate into which the well is fabricated.

12. The integrated circuit as recited in claim 11 wherein the first circuit includes a second transistor that is fabricated in the substrate without the well.

13. The integrated circuit as recited in claim 11 wherein one of the substrate bias voltage and the third substrate bias voltage is nominally a power supply voltage if no compensation is needed.

14. The integrated circuit as recited in claim 13 wherein the other one of the substrate bias voltage and the third substrate bias voltage is nominally a ground voltage if no compensation is needed.

15. A method comprising:
monitoring one or more transistors to detect a change in a threshold voltage of the transistors over time due to hot carrier effects on the transistors; and
modifying at least one substrate bias voltage supplied to transistors in circuitry that implements one or more operations for which an integrated circuit is designed responsive to the monitoring, the modifying performed to compensate for the change in a threshold voltage of the transistors.

16. The method as recited in claim 15 wherein the monitoring comprises monitoring at least one feedback signal from the circuitry.

17. The method as recited in claim 15 wherein the monitoring comprises monitoring a circuit that approximates a critical path in the circuitry.

18. The method as recited in claim 15 wherein modifying comprises modifying a substrate bias voltage supplied to a well into which one or more transistors are fabricated in the integrated circuit.

19. The method as recited in claim 18 wherein modifying comprises modifying a second substrate bias voltage that is supplied to a substrate into which the well is fabricated.
